(19) United States
(12) Patent Application Publication
(10) Pub. No.: US 2018/0155199 A1
(43) Pub. Date: Jun. 7, 2018

(54) Novel Carbon Allotrope: Protomene

(71) Applicants: Larry Burchfield, Richland, WA (US); Mohamed Al Fahim, Abu Dhabi (AE)

(72) Inventor: Larry Burchfield, Richland, WA (US)

(21) Appl. No.: 15/201,453

(22) Filed: Jul. 3, 2016

Related U.S. Application Data
(60) Provisional application No. 62/233,796, filed on Oct. 14, 2015.

(51) Int. Cl. C01B 32/15; H01L 29/167; H01B 1/04

(52) U.S. Cl. CPC C01B 32/15; C01P 2006/40; H01B 1/04; H01L 29/167

(57) ABSTRACT

The present invention provides a new and useful synthetic carbon allotrope which contains multiple clusters of carbon atoms dispersed throughout the carbon allotrope. These clusters contain carbon atoms which are bonded to four other carbon atoms by sp2 hybridized bonds. The allotrope further contains multiple surrounding carbon atoms, which are bonded to each other by sp3 hybridized bonds. One of the multiple clusters of carbon atoms is centrally located within the carbon allotrope.

### CROSS-REFERENCE TO RELATED APPLICATIONS

This patent application claims the benefit of U.S. Provisional Application Ser. No. 62/233,796, filed on 28 Sep. 2015, titled “A Novel Carbon Allotrope Protomene”.

### BACKGROUND OF THE INVENTION

### Field of Invention

The invention relates to novel carbon allotrope and compositions and uses thereof.

### Description of Prior Art

Elemental carbon occurs throughout nature in a wide variety of allotropic forms. This wide variety of allotropic forms is attributed to carbon being the only element in the periodic table known to have isomers with 0, 1, 2, or 3 dimensions. The carbon atom can hybridize electronic states in several different valence bonds which allows for a variety of different atomic bonding configurations. The isomers can have sp, sp2 or sp3 hybridization in the valence electron orbitals.

As can be seen in FIG. 1a through 1h there are eight known allotropes of carbon: a) diamond, b) graphite, c) Lonsdaleite, d) C60 (Buckminsterfullerene or buckyball), e) C540, f) C70, g) amorphous carbon, and h) single-walled carbon nanotube, or buckytube.

Diamond is one of the most well-known carbon allotrope. The carbon atoms are arranged in a lattice, which is a variation of the face-centered cubic crystal structure. Each carbon atom in a diamond is covalently bonded to four other carbons in a tetrahedron, as seen in FIG. 1a. These tetrahedrons together form a three-dimensional network of six-membered carbon rings in the chair conformation, allowing for zero bond-angle strain. This stable network of covalent bonds and hexagonal rings is the reason that diamond is so incredibly strong as a substance.

As a result, diamond exhibits the highest hardness and thermal conductivity of any bulk material. In addition, its rigid lattice prevents contamination by many elements. The surface of diamond is lipophilic and hydrophobic, which means it cannot get wet by water but can be in oil. Diamonds do not generally react with any chemical reagents, including strong acids and bases.

Graphite is another allotrope of carbon and unlike diamond; it is an electrical conductor and a semi-metal. Graphite is the most stable form of carbon under standard conditions and is used in thermochemistry as the standard state for defining the heat of formation of carbon compounds. As seen in FIG. 1b, graphite has a layered, planar structure. In each layer, the carbon atoms are arranged in a hexagonal lattice with separation of 0.142 nm, and the distance between planes (layers) is 0.335 nm. The two known forms of graphite, alpha (hexagonal) and beta (rhombohedral), have very similar physical properties (except that the layers stack slightly differently). The hexagonal graphite may be either flat or buckled. The alpha form can be converted to the beta form through mechanical treatment, and the beta form reverts to the alpha form when it is heated above 1300° C. Graphite can conduct electricity due to the vast electron delocalization within the carbon layers; as the electrons are free to move, electricity moves through the plane of the layers.

A single layer of graphite is called graphene. This material displays extraordinary electrical, thermal, and physical properties. It is an allotrope of carbon whose structure is a single planar sheet of sp2 bonded carbon atoms that are densely packed in a honeycomb crystal lattice. The carbon-carbon bond length in graphene is ˜0.142 nm, and these sheets stack to form graphite with an interplanar spacing of 0.335 nm. Graphene is the basic structural element of carbon allotropes such as graphite, charcoal, carbon nanotubes, and fullerenes. Graphene is a semi-metal or zero-gap semiconductor, allowing it to display high electron mobility at room temperature.

Another known allotrope of carbon, Lonsdaleite, is also known as “hexagonal diamond”, due to its crystal structure which has a hexagonal lattice, which is depicted in FIG. 1c. The diamond structure of typically made up of interlocking six carbon atoms, which exist in the chair conformation. However, in Lonsdaleite, some rings are in the boat conformation instead. In diamond, all the carbon-to-carbon bonds, both within a layer of rings and between the layer of rings are in the staggered conformation, which causes all four cubic-diagonal directions to be equivalent. Whereas in Lonsdaleite, the bonds between the layers are in the eclipsed conformation, which defines the axis of hexagonal symmetry.

Amorphous carbon refers to carbon that does not have a crystalline structure, as is evident by the structure depicted in FIG. 1g. Even though amorphous carbon can be manufactured, there still exist some microscopic crystals of graphite-like or diamond-like carbon. The properties of amorphous carbon depend on the ratio of sp² to sp³ hybridized bonds present in the material. Graphite consists purely of sp² hybridized bonds, whereas diamond consists purely of sp³ hybridized bonds. Materials that are high in sp³ hybridized bonds are referred to as tetrahedral amorphous carbon (owing to the tetrahedral shape formed by sp³ hybridized bonds), or diamond-like carbon (owing to the similarity of many of its physical properties to those of diamond).

Carbon nanomaterials make up another class of carbon allotropes. Fullerenes (also called buckyballs) are molecules of varying sizes composed entirely of carbon that take on the form of hollow spheres, ellipsoids, or tubes. Buckyballs and buckytubes have been the subject of intense research, both because of their unique chemistry and for their technological applications, especially in materials science, electronics, and nanotechnology. Carbon nanotubes are cylindrical carbon molecules that exhibit extraordinary strength and unique electrical properties and are efficient conductors of heat. Carbon nanobuds are newly discovered allotropes in which fullerene-like “buds” are covalently attached to the outer side walls of a carbon nanotube. Nanobuds therefore exhibit properties of both nanotubes and fullerenes.

Pure carbon and its various known allotropic forms described above provide many currently useful commercial and research applications. For example, the high thermal conductivity of diamond along with its electrically insulative properties allows for its widespread use as a heat sink material for certain solid state devices in the microelectronics industry. Graphite has been used successfully as a lubricant and a catalyst support material.

### BRIEF SUMMARY OF THE INVENTION

The present invention provides a new and useful synthetic carbon allotrope, which for purposes of the present disclosure will be termed “Protomene”. Due to the unique chemical structure of the presently disclosed carbon allotrope, compositions comprising the allotrope can be useful for incorporation for a variety of materials and applications, including, but not limited to those utilized for infrared light detection, quantum computing devices, optoelectronics, Hall effect sensors, transistors and transparent conducting electrodes.

The carbon allotrope contains multiple clusters of carbon atoms dispersed throughout the carbon allotrope. These clusters contain carbon atoms which are bonded to four other carbon atoms by sp2 hybridized bonds. The allotrope further contains multiple surrounding carbon atoms, which are bonded to each other by sp3 hybridized bonds. One of the multiple clusters of carbon atoms is centrally located within the carbon allotrope.

The multiple surrounding carbon atoms, which are bonded to each other by sp3 hybridized bonds are bonded in interlocking rings of six carbon atoms in chair and boat conformations. These conformations are in the form of hexagonal diamond or Lonsdaleite.

Therefore, the carbon allotrope contains two forms of carbon bonding, the multiple clusters and central cluster of sp2 hybridized carbons and the surrounding carbon atoms which are bonded to each other by sp3 hybridized carbons, characterized as Lonsdaleite structures. The Lonsdaleite structures of the carbon allotrope serve as the structure or stitching which holds in place the multiple clusters of sp2 bound carbon atoms.

Due to this dual natural of the carbon allotrope, various unique properties of the allotrope are present. For example, the multiple clusters of carbon atoms, including the centrally located cluster of carbon atoms are characterized by high carrier mobility, which provides conductive zones within the carbon allotrope, including a conductive central zone. Whereas, the Lonsdaleite structures formed by the surrounding carbons are characterized by electrically insulative properties. This unique combination of conductive and insulative regions within the carbon atoms lends a variety of chemical, physical and electrical properties to the carbon allotrope which makes the allotrope suitable for many applications.

The present carbon allotrope can be utilized in the production of integrated circuits, wherein a component made from the allotrope can have low noise and can be adapted for use as the channel in a filed-effect transistor. The allotrope can be further utilized in electrode devices, as a Hall-effect sensor, conductive electrodes, optoelectronics applications, optical laser devices, quantum computing devices, photovoltaic devices and superconductors.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

In the drawings:

FIG. 1a-h illustrates the structures of various known carbon allotropes.

FIG. 2 illustrates a top view of the carbon allotrope of the present invention.

FIG. 3 illustrates a side view of the carbon allotrope of the present invention.

### DETAILED DESCRIPTION

In the following Detailed Description, reference is made to the accompanying drawings, which form a part hereof, and in which is shown by way of illustration specific embodiments in which the invention may be practiced. Wherever possible, the same reference numbers are used in the drawings and the description to refer to the same or like parts. Directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

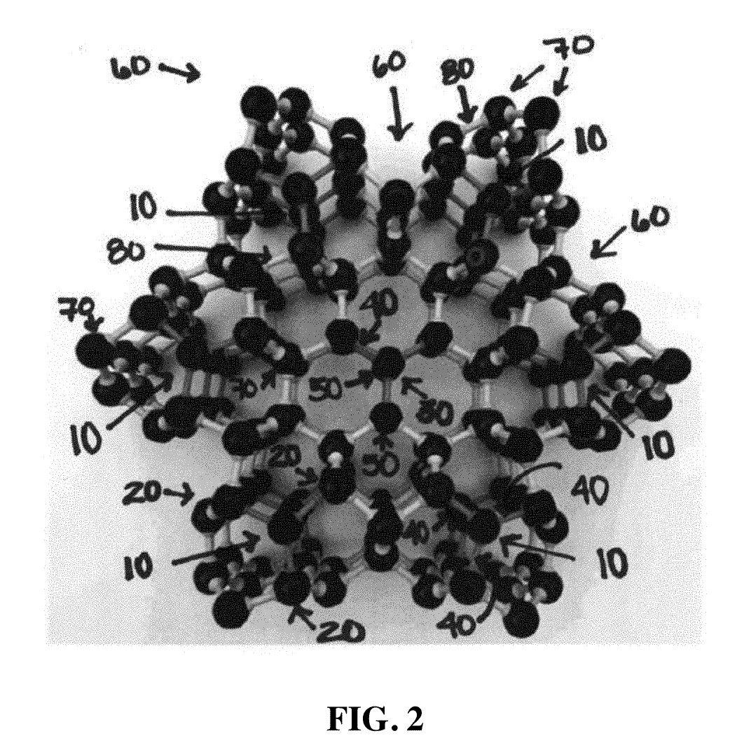

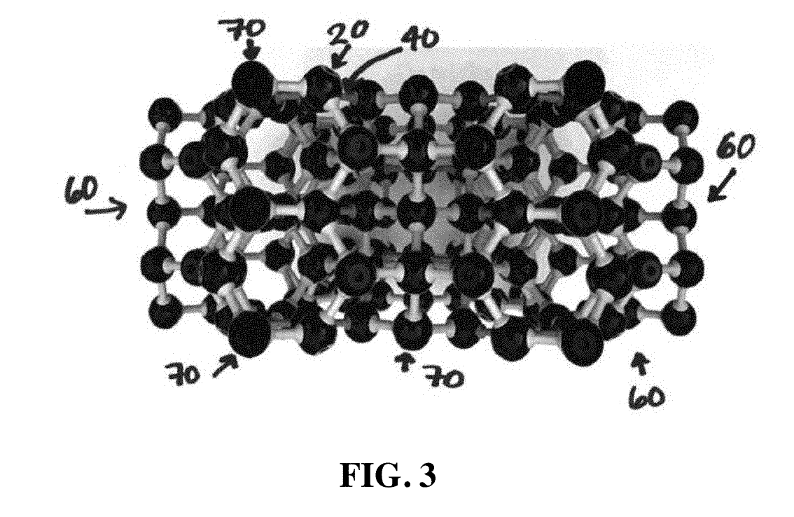

The present invention pertains to a synthetic new carbon allotrope, which is illustrated by the model in FIGS. 2 and 3. In FIG. 2, a top view of the carbon allotrope can be seen. The carbon allotrope shown in FIG. 2, termed Protomene for purposes of this disclosure, is comprised of multiple clusters 10 of carbon atoms 20 dispersed throughout the carbon allotrope. These clusters contain carbon atoms 20 which are bonded to each other by sp2 hybridized bonds 40. These sp2 hybridized bonds 40 can be seen as the dark grey bonds 40 in FIG. 2. The multiple clusters 10 are symmetrically dispersed within the carbon allotrope. In FIG. 2, six such clusters 10 can be seen located within the points of the star-like carbon allotrope.

An additional centrally located cluster 30 can be seen at the center point of the carbon allotrope in FIG. 2. This centrally located cluster 30, also contains carbon atoms 50, which are bonded to each other by sp2 hybridized bonds 40, similarly to the multiple clusters 10 located throughout the carbon allotrope, discussed above. As illustrated in FIGS. 2 and 3, the particular model of the carbon allotrope of this embodiment has three stacked vertical layers of repeating units. The three stacked layers of the multiple clusters 10 are held together by Lonsdaleite structures 60, which will be described next.

The allotrope further comprises multiple surrounding carbon atoms 70, connected to the multiple clusters 10 and the centrally located cluster 30 of carbon atoms 50. The surrounding carbon atoms 70 make up the supporting Lonsdaleite structure 60 within the carbon allotrope. The Lonsdaleite structure 60 comprised of the surrounding carbon atoms 70 is characterized by sp3 hybridized bonds 80 connecting the carbon atoms 70. The sp3 hybridized bonds 80 are depicted as the white bonds within FIGS. 2 and 3. The Lonsdaleite structures 60 have interlocking rings of six carbon atoms 70 in chair and boat conformations.

Moving now to FIG. 3, a side view of the carbon allotrope is shown. In this side view the Lonsdaleite structures 60 made up of the surrounding carbons 70 can be seen more easily. FIG. 3 shows the Lonsdaleite structures 60 as they surround the carbon atoms 20 making up the multiple clusters 10. It can be seen from this side view that the Lonsdaleite structures 60 are the outermost portion of the carbon allotrope and the support or stitching which connects and holds together the multiple clusters 10 and the central cluster 30 in the carbon allotrope.

Lonsdaleite is also known as “hexagonal diamond”, due to its crystal structure which has a hexagonal lattice. The diamond structure of typically made up of interlocking six carbon atoms, which exist in the chair conformation. However, in Lonsdaleite, some rings are in the boat conformation instead. In diamond, all the carbon-to-carbon bonds, both within a layer of rings and between the layer of rings are in the staggered conformation which causes all four cubic-diagonal directions to be equivalent. Whereas in Lonsdaleite, the bonds between the layers are in the eclipsed conformation, which defines the axis of hexagonal symmetry.

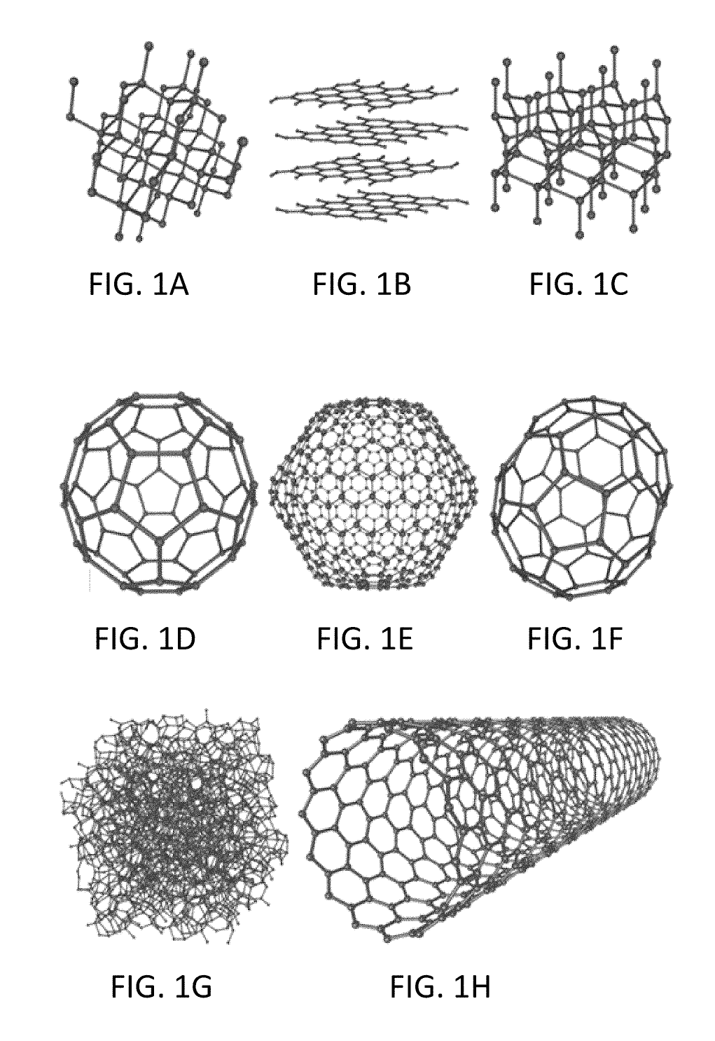

In a Lonsdaleite allotrope, as knower in the art, the hexagonal carbon rings are situated directly on top of one another between layers, as is shown in FIG. 1c. The rings however are kinked rather than planar, such that the shorter carbon-to-carbon distances, about 1.545 Angstroms, are bonded between planes, while longer carbon-to-carbon distances of 2.575 Angstroms remain unbonded. Additional bonding constraints are the carbon-to-carbon distances in the hexagonal rings, of 1.543-1.545 Angstroms, and these rings are connected both in-plane and perpendicular to the plane.

In the embodiment shown in FIGS. 2 and 3, the carbon allotrope contains two forms of carbon bonding, which results in the carbon allotrope having unique chemical, physical and electrical properties. In summary, the allotrope comprises multiple clusters 10 and centrally located cluster 30 of sp2 hybridized carbons 20 and 50, respectively and the surrounding carbon atoms 70, bonded to each other by sp3 hybridized bonds 80, making up the Lonsdaleite structures 60, which form a support or stitching for the multiple clusters 10 and the centrally located cluster 30.

This dual nature of the carbon allotrope allows for both conductive and insulating regions or zones within the allotrope. The multiple clusters 10, and the central cluster 30 which contain carbon atoms 20 and 50 respectively, display high carrier mobility, which results in the multiple clusters 10 and the central cluster 30 to be electrically conductive, thus creating electrically conductive zones within the carbon allotrope at the center of the allotrope and internally within the regions where the multiple clusters 10 are located. In the embodiment shown in FIG. 2, six such multiple clusters 10 are present and located within the “points” of the allotrope which has the configuration of a six-pointed star.

In contrast to these electrically conductive zones, the surrounding carbons 70 which make up the Lonsdaleite structure 60 of the carbon allotrope, have electrically insulative properties, thereby creating insulating regions within the carbon allotropes.

### Properties and Utilization of the Carbon Allotrope

Due to the unique chemical, physical and electrical properties of the carbon allotrope, the use of the allotrope in many fields and for various applications is possible. The Lonsdaleite outer regions of the allotrope provide hard insulating portions, with a conductive center, provided by the centrally located cluster 30 made of carbon atoms 50, which are characterized by high carrier mobility.

For a non-limiting example, the carbon allotrope can be used in the production of integrated circuits, wherein a component made from the allotrope can have low noise and can be adapted for use as the channel in a filed-effect transistor. As another example the carbon allotrope can be used in an electronic computing device including a series of transistors, where at least one transistor includes the carbon allotrope.

In another example, the carbon allotrope is utilized in an electrode device, wherein a series of centrally located carbon clusters 30 of the carbon allotrope of this invention are adapted to act as a transparent conducting electrode.

In further examples, the carbon allotrope is adapted for use as optical laser device, which includes the carbon allotrope, wherein an electric field is induced on the centrally located carbon cluster 30. Additionally, the carbon allotrope can be utilized in optoelectronic devices, including devices selected from a group consisting of a transparent film, a touchscreen, a light emitter, and a plasmonic device capable of confining light and/or altering wavelengths.

Other examples of the utility of the present carbon allotrope include Hall Effect sensors, wherein the sensor includes the carbon allotrope. In yet other examples, the invention features a molecular structure including two layers of the carbon allotrope and an insulating layer disposed between those two layers, wherein an electric field produced by holes left by photo-freed electrons in one layer affect a current running through the other layers.

### Doping and Synthesis Methods of the Carbon Allotrope

For further enhancement of conducting capabilities the carbon allotrope is capable of being doped with a metal element, including but not limited to gold, silver, platinum group metals or base metal copper ions for conduction charge in between the conductive sp2 bound carbon atoms. Further doping with p-type and n-type materials is also envisioned for the formation of a transistor.

The presently disclosed carbon allotrope can be synthesized through various techniques presently known and existing in the art. These include but are not limited to chemical vapor deposition (CVD), plasma enhanced chemical vapor deposition (PECVD), filament assisted chemical vapor deposition, arc discharge or laser ablation methods and molecular printing. The CVD method is commonly known in the art, and utilizes a carbon containing source, usually in gaseous foam, which is decomposed at elevated temperatures and passes over a transition metal catalyst (typically Fe, Co, Ag or Ni). CVD is known to produce a high yield of carbon allotropes, although more accurate structures are generally capable of production through by arc or laser ablation methods.

While selected embodiments have been selected to be illustrated of the present invention, and specific examples have been described herein, it will be obvious to those skilled in the art that various changes and modifications may be aimed to cover in the appended claims. It will, therefore, be understood by those skilled in the art that the particular embodiments of the invention presented here are by way of illustration only, and are not meant to be in any way restrictive; therefore, numerous changes and modifications may be made, and the full use of equivalents resorted to, without departing from the spirit or scope of the invention as outlined in the appended claims.

1. A composition of matter comprising:
a carbon allotrope comprising multiple clusters of carbon atoms,
said carbon atoms bonded to other carbon atoms by sp2 hybridized bonds; and multiple surrounding carbons,
said surrounding carbons bonded to each other by sp3 hybridized bonds;
wherein one of said clusters of carbon atoms is centrally located within the carbon allotrope, and
wherein the carbon allotrope has a star-like configuration.

2. A composition of matter as in claim 1, wherein the surrounding carbons bonded to each other by sp3 hybridized bonds, are bonded in interlocking rings of six carbon atoms in chair and boat conformations.

3. A composition of matter as in claim 1, wherein said multiple clusters of carbon atoms are characterized by high carrier mobility which imparts conductivity to said multiple clusters.

4. A composition of matter as in claim 1, wherein the carbon allotrope comprises six of said multiple clusters of carbon atoms and one centrally located cluster.

5. A composition of matter as in claim 1, wherein said surrounding carbons form hexagonal units of Lonsdaleite.

6. A composition of matter as in claim 1, where said surrounding carbons form electrically insulating portions of the carbon allotrope.

7. A composition of matter as in claim 1, wherein said centrally located cluster of carbon atoms is electrically conductive.

8. A composition of matter as in claim 1, wherein the carbon allotrope is comprised of both electrically conductive and electrically insulating regions

9. A composition of matter according to claim 1, wherein the carbon allotrope is doped with a metallic element, selected from a group consisting of silver, gold, copper and platinum.

10. A composition of matter according to claim 1, wherein the carbon allotrope is doped with an n-type or p-type material for the formation of a transistor.

11. A composition of matter according to claim 1, wherein the carbon allotrope in said composition is incorporated in devices or applications selected from a group consisting of integrated circuits, optoelectronic devices, semiconductor devices, Hall effect sensors, quantum dots, optical absorption/modulation device, infrared light detection devices, photovoltaic cells, conductive electrodes, fuel cells, supercapacitors, molecular absorption sensors and piezoelectric devices.

12. A composition of matter according to claim 1, where the carbon allotrope is configured as an electrode device, wherein the centrally located carbon cluster of said carbon allotrope is adapted to act as a transporting conduction electrode.
